(19) United States
(12) Patent Application Publication
(10) Pub. No.: US 2026/0305036 A1
(43) Pub. Date: Oct. 1, 2026

(54) LIGHT-EMITTING ASSEMBLY, DISPLAY PANEL, AND PREPARATION METHOD FOR LIGHT-EMITTING ASSEMBLY

(71) Applicants: Beijing BOE Technology Development Co., Ltd., Beijing (CN); BOE Technology Group Co., Ltd., Beijing (CN)

(72) Inventors: Wanpeng TENG, Beijing (CN); Jintao PENG, Beijing (CN); Meirong LU, Beijing (CN); Kai GUO, Beijing (CN); Chunfang ZHANG, Beijing (CN); Weixing LIU, Beijing (CN); Zhiqiang XU, Beijing (CN); Huanhuan WANG, Beijing (CN); Yuwei YAN, Beijing (CN)

(21) Appl. No.: 19/489,897

(22) PCT Filed: Jun. 6, 2024
(86) PCT No.: PCT/CN2024/097741

§ 371 Date: Dec. 4, 2025

(30) Foreign Application Priority Data
Jun. 6, 2023 (CN) 202310667117.4

(51) Int. Cl. H10H 29/49; H10H 20/812; H10H 20/85; H10H 29/01; H10H 29/32

(52) U.S. Cl. CPC H10H 29/49; H10H 20/812; H10H 20/8508; H10H 29/012; H10H 29/32

(57) ABSTRACT

The light-emitting assembly comprises: a light-emitting unit, a driving unit and a plurality of pins, wherein the light-emitting unit comprises a first electrode, a second electrode and a light-emitting portion; the driving unit comprises a third electrode, a fourth electrode and a driving portion, the third electrode and the fourth electrode are both located on the side of the driving unit that faces the light-emitting unit, the third electrode is electrically connected to the first electrode, and the fourth electrode is electrically connected to the second electrode; the plurality of pins are all located on the side of the driving unit that faces away from the light-emitting unit, and are electrically connected to the driving circuit; a first filling portion, a second filling portion and a third filling portion are comprised between the light-emitting unit and the driving unit.

### CROSS-REFERENCE TO RELATED APPLICATIONS

The present application is a U.S. National Phase Entry of International PCT Application No. PCT/CN2024/097741 having an international filing date of Jun. 6, 2024, which claims priority to Chinese Patent Application No. 202310667117.4 filed on Jun. 6, 2023. The above-identified applications are incorporated by reference herein in their entireties.

### TECHNICAL FIELD

Embodiments of the present disclosure relate to, but are not limited to, the field of displays, and particularly relate to a light emitting assembly, a display panel, and a manufacturing method for the light emitting assembly.

### BACKGROUND

A Micro Light Emitting Diode (Micro LED) display panel includes a driving unit integrated on a display backplane and a light emitting chip bonded and connected with the driving unit, wherein the driving unit is located in the display backplane and is integrated with the display backplane into an integral structure by semiconductor processing technology. However, due to individual defects of the driving unit and difficulty in repairing, the production yield of the display backplane is not high, and finally the display panel has many defects.

### SUMMARY

The following is a summary of subject matter described in the present disclosure in detail. This summary is not intended to limit the protection scope of claims.

An embodiment of the present disclosure provides a light emitting assembly, a display panel, and a manufacturing method of a light emitting assembly, including: a light emitting unit including a first electrode, a second electrode, and a light emitting portion electrically connected with the first electrode and the second electrode, respectively; a driving unit including a third electrode, a fourth electrode, and a driving portion, wherein each of the third electrode and the fourth electrode is located on a side of the driving unit facing the light emitting unit, the third electrode and the fourth electrode are electrically connected with a driving circuit in the driving portion, respectively, the third electrode is electrically connected with the first electrode, and the fourth electrode is electrically connected with the second electrode; a plurality of pins, each located on a side of the driving unit facing away from the light emitting unit, and electrically connected with the driving circuit; wherein a first filling portion, a second filling portion, and a third filling portion are included between the light emitting unit and the driving unit, the first filling portion surrounds the second filling portion and the third filling portion, and a thickness of the first filling portion is greater than a thickness of the second filling portion and a thickness of the third filling portion, respectively; the second filling portion is located between the first electrode and the third electrode, and is disposed in contact with the first electrode and the third electrode, respectively; the third filling portion is located between the second electrode and the fourth electrode, and is disposed in contact with the second electrode and the fourth electrode, respectively.

In some embodiments, at least one pin of the plurality of pins includes a first metal layer and a second metal layer that are stacked, and the first metal layer is located between the second metal layer and the driving unit; wherein a material of the first metal layer includes nickel, and a material of the second metal layer includes gold.

In some embodiments, the first filling portion has insulation, the second filling portion has conductivity, and the third filling portion has conductivity; the first filling portion is in direct contact with the second filling portion; the first filling portion is in direct contact with the third filling portion; a portion of the first filling portion is located between the second filling portion and the third filling portion.

In some embodiments, a density of the first filling portion is less than a density of the second filling portion; the density of the first filling portion is less than a density of the third filling portion.

In some embodiments, the light emitting assembly includes a transparent substrate located on a side of the light emitting unit away from the driving unit; an orthographic projection of the first filling portion on a plane on which the transparent substrate is located within the transparent substrate.

In some embodiments, an outer contour of the orthographic projection of the first filling portion on the plane on which the transparent substrate is located coincides with an outer contour of the transparent substrate.

In some embodiments, the light emitting assembly includes a transparent substrate located on a side of the light emitting unit away from the driving unit; the light emitting unit includes a light emitting portion including: a raised electrode, a first insulation layer, and a second doped layer, a multiple quantum well layer, and a first doped layer which are sequentially stacked in a direction away from the transparent substrate; wherein, the second electrode is located on a side of the first doped layer away from the multiple quantum well layer, and the first doped layer is electrically connected with the second electrode; the raised electrode is located between the second doped layer and the first electrode, and is electrically connected with the second doped layer and the first electrode, respectively; the first insulation layer is located on a side of the first doped layer away from the transparent substrate, and is disposed in contact with the first doped layer.

In some embodiments, the first filling portion includes a first sub-filling portion and a second sub-filling portion; an orthographic projection of the first sub-filling portion on a plane on which the transparent substrate is located is not overlapped with an orthographic projection of the light emitting unit on the plane on which the transparent substrate is located; wherein the second sub-filling portion is at least partially located between the raised electrode and the multiple quantum well layer, and the first sub-filling portion surrounds a whole arrangement of the raised electrode, the multiple quantum well layer, and the second sub-filling portion.

In some embodiments, a thickness of the first sub-filling portion is greater than or equal to a distance between the first insulation layer and the driving portion; a thickness of the second sub-filling portion is equal to a maximum distance between the first insulation layer and the driving portion.

In some embodiments, the first sub-filling portion includes at least a portion located between the transparent substrate and the driving portion; a relationship between a thickness T1 of the first sub-filling portion located between the transparent substrate and the driving portion and a thickness T2 of the second sub-filling portion satisfies: 0.5 T1<T2<0.95 T1.

In some embodiments, the light emitting assembly includes a plurality of light emitting units and driving units corresponding to the plurality of light emitting units; the plurality of light emitting units include first color light emitting units, second color light emitting units, and third color light emitting units, wherein a first color emitted by a first color light emitting unit, a second color emitted by a second color light emitting unit, and a third color light emitting unit by a third color light emitting unit are different from each other; a light emitting unit includes a color film layer, a color conversion layer, and a light emitting portion which are sequentially stacked in a direction away from the transparent substrate; a light emission color of the light emitting portion is blue; wherein the light emitting portion includes a first light emitting portion located in the first color light emitting unit, a second light emitting portion located in the second color light emitting unit, and a third light emitting portion located in the third color light emitting unit.

In some embodiments, the driving unit includes a base substrate having connection vias and connection structures located in the connection vias, and the driving circuit being located on a side of the base substrate close to the light emitting unit; the pins are located on a side of the base substrate away from the driving circuit, and the pins are in contact with the connection structures, and the pins are connected with the driving circuit through the connection structures. In some embodiments, the driving circuit includes one or more thin film transistors, and a thin film transistor includes a gate, a source, and a drain; one of the plurality of pins is connected with the source of the thin film transistor for supplying the driving circuit with a data drive signal transmitted from a display backplane in a display panel.

In some embodiments, the driving circuit includes a buffer layer, an active layer, a first gate insulation layer, a first gate layer, a second gate insulation layer, a second gate layer, an interlayer dielectric layer, a source-drain layer, and a planarization layer which are sequentially stacked on a side of the base substrate; the third electrode and the fourth electrode are located on a side of the planarization layer away from the base substrate; the active layer includes one or more active patterns corresponding to the one or more thin film transistors, an active pattern including a source region, a drain region, and a channel region; the source and the drain of the thin film transistor are located in the source-drain layer, the source and the source region of the thin film transistor are connected, and the drain and the drain region of the thin film transistor are connected; the first gate layer includes one or more gate patterns corresponding to the one or more thin film transistors, and the channel region is an overlapping area of an orthographic projection of a gate pattern on the base substrate and an orthographic projection of the active pattern on the base substrate.

In some embodiments, areas of orthographic projections of the pins on the base substrate are greater than areas of orthographic projections of the connection structures on the base substrate, and the orthographic projections of the pins on the base substrate cover the orthographic projections of the connection structures on the base substrate.

On the other hand, an embodiment of the present disclosure provides a display panel, wherein the display panel includes a display backplane and a plurality of the light emitting assemblies according to any one of the embodiments of the present disclosure arranged in an array on a side of the display backplane; wherein the display backplane is configured to supply drive signals to the driving units through a plurality of pins in the light emitting assemblies, so that the driving units drive the light emitting units to emit light.

On the other hand, an embodiment of the present disclosure provides a manufacturing method of a light emitting assembly for manufacturing the light emitting assembly according to any one of the embodiments of the present disclosure, including: an anisotropic conductive film to be compressed, a light emitting unit, and a driving unit are compressed and bonded to obtain a bonded light emitting assembly, wherein the compressed and bonded anisotropic conductive film includes: a first filling portion, a second filling portion, and a third filling portion; the first filling portion surrounds the second filling portion and the third filling portion, and a thickness of the first filling portion is greater than a thickness of the second filling portion and a thickness of the third filling portion, respectively; the second filling portion is located between a first electrode of the light emitting unit and a third electrode of the driving unit, and is disposed in contact with the first electrode and the third electrode, respectively; the third filling portion is located between a second electrode of the light emitting unit and a fourth electrode of the driving unit, and is disposed in contact with the second electrode and the fourth electrode, respectively; the bonded light emitting assembly is placed in a target solution to perform an electroplating process or an electroless plating process, to obtain the light emitting assembly having a plurality of pins on the driving unit.

Other aspects of the present disclosure may be comprehended after the drawings and the detailed descriptions are read and understood.

### BRIEF DESCRIPTION OF DRAWINGS

In order to describe technical solutions in embodiments of the present disclosure or the prior art more clearly, the drawings to be used for describing the embodiments or the prior art will be introduced below in brief. Apparently, the drawings described below are only some embodiments of the present disclosure, and those of ordinary skills in the art may also obtain other drawings according to these drawings without paying any inventive effort.

FIG. 1 is a schematic cross-sectional structural diagram of a light emitting assembly according to an embodiment of the present disclosure.

FIG. 2 is a schematic cross-sectional structural diagram of a light emitting assembly without a first filling portion according to an embodiment of the present disclosure.

FIG. 3 is a schematic diagram of a first filling portion provided by an embodiment of the present disclosure surrounding a light emitting unit.

FIG. 4 is a process flow chart for manufacturing a light emitting assembly according to an embodiment of the present disclosure.

FIG. 5A is a schematic cross-sectional structural diagram of a light emitting assembly according to an embodiment of the present disclosure.

FIG. 5B is a partial schematic diagram of FIG. 5A.

FIG. 6 is a schematic cross-sectional structural diagram of a driving circuit according to an embodiment of the present disclosure.

FIG. 7 is a flow chart of a manufacturing method for a light emitting assembly according to an embodiment of the present disclosure.

### DETAILED DESCRIPTION

In order to make objectives, technical solutions, and advantages of the embodiments of the present disclosure clearer, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Based on the described embodiments of the present disclosure, all other embodiments obtained by those of ordinary skills in the art without paying any inventive effort are within the protection scope of the present disclosure.

Unless otherwise defined, technical terms or scientific terms used in the present disclosure should have the meanings as commonly understood by those of ordinary skills in the field to which the present disclosure belongs to. The term “first”, “second” and similar terms used in the present disclosure do not indicate any order, quantity, or importance, but are used only for distinguishing different components. “Include”, “contain”, or similar words mean that elements or objects appearing before the words cover elements or objects listed after the words and their equivalents, but do not exclude other elements or objects. “Connect”, “couple”, or similar words are not limited to a physical or mechanical connection, but may include an electrical connection, whether direct or indirect. “Upper”, “lower”, “left”, and “right”, etc., are used for representing a relative positional relationship, and when an absolute position of a described object is changed, the relative positional relationship may also be correspondingly changed.

“A and B being disposed in a same layer” mentioned in the present disclosure means that A and B are formed simultaneously through a same patterning process, and a “thickness” of a film layer is a dimension of the film layer in a direction perpendicular to the display apparatus. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In order to keep following description of the embodiments of the present disclosure clear and concise, detailed description of known functions and known components are omitted in the present disclosure.

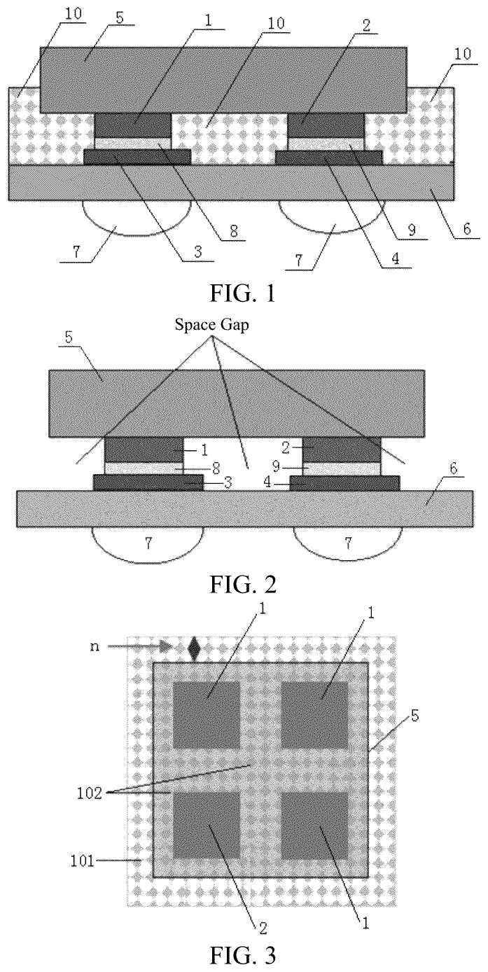

An embodiment of the present disclosure provides a light emitting assembly with a cross-sectional structure as shown in FIG. 1. The light emitting assembly includes:
a light emitting unit including a first electrode 1, a second electrode 2, and a light emitting portion 5 electrically connected with the first electrode 1 and the second electrode 2, respectively;
a driving unit including a third electrode 3, a fourth electrode 4, and a driving portion 6, wherein each of the third electrode 3 and the fourth electrode 4 is located on a side of the driving unit facing the light emitting unit, the third electrode 3 and the fourth electrode 4 are electrically connected with a driving circuit 63 (see FIG. 5) in the driving portion 6, respectively, the third electrode 3 is electrically connected with the first electrode 1, and the fourth electrode 4 is electrically connected with the second electrode 2;
a plurality of pins 7, each located on a side of the driving unit facing away from the light emitting unit, and electrically connected with the driving circuit 63;
wherein a first filling portion 10, a second filling portion 8, and a third filling portion 9 are included between the light emitting unit and the driving unit, the first filling portion surrounds the second filling portion and the third filling portion, and a thickness of the first filling portion 10 is greater than a thickness of the second filling portion 8 and a thickness of the third filling portion 9, respectively; the second filling portion 8 is located between the first electrode 1 and the third electrode 3, and is disposed in contact with the first electrode 1 and the third electrode 3, respectively; the third filling portion 9 is located between the second electrode 2 and the fourth electrode 4, and is disposed in contact with the second electrode 2 and the fourth electrode 4, respectively.

When manufacturing a Micro LED display panel in related art, in order to realize color display, it is necessary to transfer and bond light emitting chips of different colors to a display backplane integrated with a driving unit, and light emitting chips of same colors are transferred at same times, while light emitting chips of different colors are transferred at different times. That is, the number of times of transfer is the number of colors of the light emitting chips. Exemplarily, when the light emitting chips include light emitting chips of three colors, for example, including a red (R) light emitting chips, green (G) light emitting chips, and blue (B) light emitting chips, three times of transfer are required. When manufacturing Micro LED display panels with this scheme, there are many times of transfer and the process is complicated.

Moreover, in order to reduce the manufacturing cost of Micro LED display panel, the size of the display backplane cannot be designed too large, because once the drive backplane is designed too large, if some of the light emitting chips fail to emit light after transfer, the entire product will be scrapped and the cost will be high. Therefore, if this scheme needs to realize large-size display, it can only be realized by splicing, and the display effect is poor.

In an embodiment of the present disclosure, a display chip and a driver unit are separately bonded. For a red, green and blue micro display chip (RGB Micro LED), it can be bonded with the driver unit to form a new Active-Matrix Light-Emitting Diode (AM-LED) chip with its own driver circuit 63. The AM-LED chip includes the red, green and blue light emitting chip and the driving unit for the light emitting chip. Therefore, no matter how large a display panel needs to be manufactured, a corresponding number of AM-LED chips and display backplanes are transferred and bonded at one time to realize manufacturing of a glass-based color Light-Emitting Diode (LED) display panel. And, the scheme only needs to carry out one transfer process, and the process is relatively simple. Moreover, large-size display can be realized without splicing, which can improve a glass utilization rate of the display backplane, thereby reducing costs.

Moreover, the AM-LED chips can realize an electrical and optical dual detection through detection technology, and chips with both optical performance and drive performance that meet the requirements can be screened out. In this way, compared with the scheme in which the driving circuit 63 is integrated on the display backplane to form the display panel, it is more beneficial to improve the chip yield on the display panel, and it is also convenient to repair and replace defective chips.

Before the AM-LED chip is bonded to the display backplane, it is necessary to make the pins 7 (Bump) for bonding connection on the AM-LED chip, and an electroplating process or an electroless plating process is usually used during the manufacturing of the pins 7. Among them, when the pins 7 are manufactured through the electroplating process or the electroless plating process, the AM-LED chip needs to be placed in a specific solution. Since the electrodes after the bonding connection between the AM-LED chip and the driving unit comes into contact with the solution, short circuit, open circuit or device failure may be caused. The cross-sectional structure of the above-described light emitting assembly in which the first filling portion 10 is not disposed may be as shown in FIG. 2, and the space gap existing therein may be penetrated with the plating solution during the plating of the pins 7.

However, the first filling portion 10 is filled in the gap between the electrical connection portion between the light emitting unit and the driving unit according to the embodiment of the present disclosure, and the thickness of the first filling portion 10 is greater than the thickness of the second filling portion 8 and the third filling portion 9, respectively, so that at least the second filling portion 8 and the third filling portion 9 can be protected from corrosion during the process of plating the pins 7. By controlling the disposed thickness of the first filling portion 10, it can be ensured that each of the second filling portion 8, the third filling portion 9, and even the electrodes of the light emitting assembly is not corroded by the plating solution, and thus there will be no open circuit or device failure issue in the light emitting assembly, further improving product performance.

In actual implementation, the thicker the thickness of the first filling portion 10, the less the first electrode 1 and the second electrode 2 are exposed, and the less the portions of the first electrode 1 and the second electrode 2 are corroded by the electroplating solution in the process of subsequent electroplating of the pins 7. In an alternative embodiment, the thickness of the first filling portion 10 is disposed to be greater than a sum of the thickness of the first electrode 1, the thickness of the third electrode 3 and a thickness of the second filling portion 8; since the thickness of the second electrode 2 is the same as the thickness of the first electrode 1, the thickness of the fourth electrode 4 is the same as the thickness of the third electrode 3, and the thickness of the third filling portion 9 is the same as the thickness of the second filling portion 8, the thickness of the above-described first filling portion 10 may be greater than a sum of the thickness of the second electrode 2, the thickness of the fourth electrode 4, and a thickness of the third filling portion 9.

In some embodiments, the thickness of the first filling portion 10 is greater than a sum of the thickness of the first electrode 1, the thickness of the third electrode 3, and the thickness of the second filling portion 8. Referring to FIG. 1, the first filling portion 10 has at least a first thickness portion having a first thickness and a second thickness portion having a second thickness, the first thickness being greater than a distance between a first surface of the light emitting portion 5 and a first surface of the driving portion 6, and less than or equal to a distance between a second surface of the light emitting portion 5 and the first surface of the driving portion 6; the second thickness is equal to or less than the distance between the first surface of the light emitting portion 5 and the first surface of the driving portion 6; wherein, a second surface of the light emitting portion 5 is a surface of the light emitting portion 5 away from the driving portion 6, and the first surface of the driving portion 6 and the first surface of the light emitting portion 5 are disposed opposite each other.

In some embodiments, the first filling portion 10 is disposed to surround the light emitting unit including a plurality of electrodes connected with the driving unit, and the plurality of electrodes include the first electrode 1 and the second electrode 2. Referring to FIG. 3, the number of electrodes is, for example, four, including three first electrodes 1 and one second electrode 2, wherein the three first electrodes 1 respectively correspond to three sub-pixels of red, green and blue of the light emitting unit, and provide drive signals for the three sub-pixels respectively; the one second electrode 2 is electrically connected with the red, green and blue sub-pixels, respectively, as a common electrode; correspondingly, the driving unit also has four electrodes, which are electrically connected with the four electrodes of the light emitting unit, respectively. For example, a first electrode 1 may be an anode of the light emitting unit, and a second electrode 2 may be a cathode of the light emitting unit. For example, a first electrode 1 may be a cathode of the light emitting unit, and a second electrode 2 may be an anode of the light emitting unit. Exemplarily, in order to ensure that the first filling portion 10 has a better protective effect, referring to FIG. 3, the first filling portion 10 has a first thickness portion and a second thickness portion, the thickness of the first thickness portion is a first thickness, and the thickness of the second thickness portion is a second thickness, wherein the first thickness portion 101 is disposed around the second thickness portion 102, and the first thickness portion 101 and the second thickness portion 102 are disposed in contact with each other, wherein a minimum distance n between an inner peripheral boundary and a peripheral boundary of the first thickness portion 101 is greater than or equal to 20 microns. In one embodiment, an orthographic projection of the inner peripheral boundary of the first thickness portion 101 on a plane on which the driving portion 6 is located coincides with an orthographic projection of the light emitting portion 5 on a plane on which the driving portion 6 is located. It should be noted that, the plane on which the drive unit 6 is located can be understood as a plane perpendicular to a lamination direction of a film layer of the driving portion 6.

In some embodiments, the first filling portion 10 is in direct contact with the second filling portion 8, the first filling portion 10 is also in direct contact with the third filling portion 9, a part of the first filling portion 10 is located between the second filling portion 8 and the third filling portion 9, that is, a space gap between the anode and the cathode of the light emitting unit due to inability to contact (that is, the space gap in the middle of FIG. 2) is also filled by the first filling portion 10, and the enclosure formed by the first filling portion 10 surrounding the second filling portion 8 and the third filling portion 9 is completely surrounds the second filling portion 8 and the third filling portion 9.

In order to ensure that a basic function of the light emitting assembly is not destroyed, the above-described first filling portion 10 should have insulation, the second filling portion 8 should have conductivity, and the third filling portion 9 should also have conductivity. The first filling portion 10, the second filling portion 8, and the third filling portion 9 may be made of different materials, or may be made of the same material. If the first filling portion 10, the second filling portion 8, and the third filling portion 9 are made of different materials, it is necessary to additionally increase a process of manufacturing the first filling portion 10 as compared to the first filling portion 10, the second filling portion 8, and the third filling portion 9 being made of the same material.

Since the first filling portion 10, the second filling portion 8, and the third filling portion 9 have different conductivity, it is necessary to consider that a same material should have different conductivity in different states when selecting the material for manufacturing. In an embodiment of the present disclosure, an anisotropic conductive film (ACF) is selected as an example, which has insulation in a normal state or in a case where it is not compressed to a certain proportion, and starts to have conductivity after being compressed to a certain proportion.

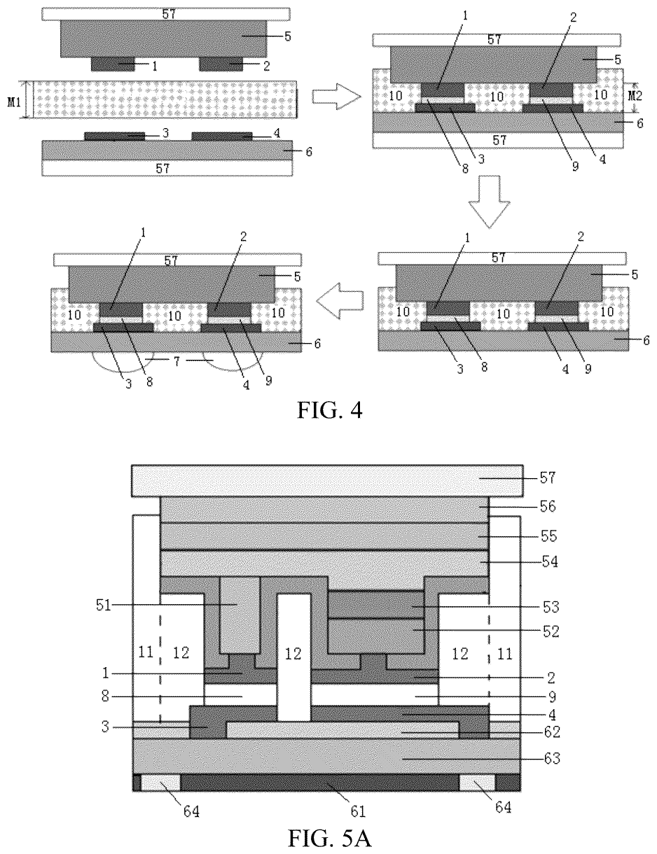

In some embodiments, the process flow of manufacturing the light emitting assembly using the anisotropic conductive film can be as shown in FIG. 4. First, a driving unit, a light emitting unit and an anisotropic conductive film are prepared separately, and then the light emitting unit and the driving unit are bonded according to a predetermined processing process to compress the anisotropic conductive film between the first electrode 1 and the third electrode 3 into a second filling portion 8, the anisotropic conductive film between the second electrode 2 and the fourth electrode 4 into a third filling part 9, and the other anisotropic conductive film constitutes the first filling part 10. Subsequently, a glass substrate under the driving unit is removed, and the pins electrically connected with the driving unit are manufactured on a surface after the glass substrate being removed, so that the driving unit is connected with a data line through the pins, to receive a control signal.

In order to ensure that the first filling portion 10 can provide sufficient protection, a density of the first filling portion 10 may be less than a density of the second filling portion 8, and the density of the first filling portion 10 may be less than a density of the third filling portion 9, so that the first filling portion 10 can be tightly wrapped around an outside of the second filling portion 8 and an outside of the third filling portion 9 to avoid corrosion of the electroplating solution during the electroplating process.

In some embodiments, the second thickness portion 102, the second filling portion 8, and the third filling portion 9 are formed by compressing the anisotropic conductive film; a relationship between a thickness M1 of the second thickness portion 102 before being compressed and a second thickness M2 satisfies 0.5 M1<M2<0.95 M1. Herein, when M2 is less than 95% of M1, it is possible to avoid defects such as bubbles and delamination due to insufficient filling of a second sub-filling portion 12 in a thickness direction; and, when M2 is more than 50% of M1, it is possible to prevent the second sub-filling portion 12 from overflowing due to excessive thickness of the filling portion, wherein the overflowing causes fewer conductive particles in the second filling portion 8 and the third filling portion 9, resulting in conductive failure. For example, the second thickness can be determined by M2≥k*d+1, where k is an upper limit of a compression ratio of the ACF in which conductive particles have good conductivity, d is an average particle size of the conductive particles in a compression direction before compression, and 1 is a sum of a distance between a surface of the first electrode 1 close to the second filling portion 8 and a surface of the light emitting portion 5 close to the first electrode 1 and a distance between a surface of the third electrode 3 close to the second filling portion 8 and the driving portion 6 close to the third electrode 3, that is, 1 is a sum of a thickness (called as a height) of the first electrode 1 and a thickness of the third electrode 3, or a sum of a thickness of the second electrode 2 and a thickness of the fourth electrode 4. Therefore, k*d is a minimum degree of compression to make the conductive particles conductive in the compression direction. For example, M2−k*d+1. For example, M2>k*d+1. For example, if the average particle size in the compression direction is 2 microns, and the compression of the conductive particles by 20%-80% is a good conductivity range, then d is 2 microns and k is 80%. In this way, it can guide on how to design the second thickness M2.

Since the embodiment of the present disclosure relates to the first electrode 1 and the second electrode 2 of the light emitting unit and the third electrode 3 and the fourth electrode 4 of the driving unit, main structures of the light emitting portion 5 and the driving portion 6 thereof are only schematically shown in FIG. 1, and the structures of the light emitting unit and the driving unit are not limited to the embodiment of the present disclosure, and as long as the first electrode 1 is electrically connected the third electrode 3, the second electrode 2 electrically connected the fourth electrode 4, and there is a space around the two electrical connections after connection, they are applicable to the solution provided in the embodiment of the present disclosure.

The embodiment of the present disclosure provides a light emitting assembly, which bonds a light emitting unit and a driving unit to form a new chip with a driving circuit 63. Only one-time transfer bonding is needed for the light emitting assembly and a display backplane, the process is simple, and the product yield is improved. A space gap between the electrical connections of the light emitting unit and the driving unit is filled with the first filling portion 10. A thickness of the first filling portion 10 is greater than that of a second filling portion 8 and a third filling portion 9, respectively, which can at least protect the second filling portion 8 and the third filling portion 9 from corrosion during the electroplating process of the pins 7. By controlling the thickness of the first filling portion 10, it can ensure that the second filling portion 8, the third filling portion 9, and even electrodes of the light emitting assembly are not corroded by the electroplating solution, and the light emitting assembly will not have short circuits or device failures, thereby improving product performance.

The pins 7 of the embodiment of the present disclosure is formed by electroplating, and at least one pin 7 of the plurality of pins 7 includes a first metal layer and a second metal layer that are stacked, and the first metal layer is located between the second metal layer and the driving unit; a material of the first metal layer may include nickel, and a material of the second metal layer may include gold. In the subsequent process, the pins 7 so designed can be fixedly connected with pads of the display backplane by a soldering process.

As shown in FIG. 4, the light emitting assembly of the embodiment of the present disclosure includes a transparent substrate 57 located on a side of the light emitting unit away from the driving unit, and the transparent substrate 57 is, for example, a glass substrate. As shown in FIG. 4, in an alternative embodiment, an orthographic projection of the first filling portion 10 on a plane on which the transparent substrate 57 is located within the transparent substrate 57, for example, an outer contour of the orthographic projection of the first filling portion 10 on the plane on which the transparent substrate 57 is located coincides with an outer contour of the transparent substrate 57.

In some embodiments, a structure of the light emitting portion 5 of the light emitting unit may be as shown in FIG. 5A, and the light emitting portion 5 includes: a raised electrode 51, a first insulation layer 58, and a second doped layer 54, a multiple quantum well layer 53, and a first doped layer 52 which are sequentially stacked in a direction away from the transparent substrate 57; wherein, the second electrode 2 is located on a side of the first doped layer 52 away from the multiple quantum well layer 53, and the first doped layer 52 is electrically connected with the second electrode 2; the raised electrode 51 is located between the second doped layer 54 and the first electrode 1, and is electrically connected with the second doped layer 54 and the first electrode 1, respectively; the first insulation layer 58 is located on the side of the first doped layer 52 away from the transparent substrate 57, and is disposed in contact with the first doped layer 52.

An orthographic projection of the above described raised electrode 51 on the transparent substrate 57 is located inside an orthographic projection of the second doped layer 54 on the transparent substrate 57; an orthographic projection of the first doped layer 52 on the transparent substrate 57 is located inside the orthographic projection of the second doped layer 54 on the transparent substrate 57. As shown in FIG. 5B, the first insulation layer 58 includes a first portion 581, a second portion 582, and a third portion 583, wherein the first portion 581 is provided with a first via, the first via is filled with a portion of the first electrode 1, and the first portion 581 and the portion of the first electrode 1 jointly wrap the raised electrode 51; the second portion 582 is provided with a second via, the second via is filled with a portion of the second electrode 2, and the second portion 582 and the portion of the second electrode 2 jointly wrap the first doped layer 52 and the multiple quantum well layer 53; the third portion 583 is disposed in contact with the first portion 581 and the second portion 582, respectively, forming a continuous film layer. For example, a distance between the third portion 583 and the driving portion 6 is greater than a distance between the first portion 581 and the driving portion 6; the distance between the third portion 583 and the drive unit 6 is greater than a distance between the second portion 582 and the drive unit 6. For example, the third portion 583 may be in direct contact with the second doped layer 54.

For example, the first doped layer 52 is n-type doped and the second doped layer 54 is p-type doped. For another example, the first doped layer 52 is p-type doped, and the second doped layer 54 is n-type doped.

In some embodiments, the first filling portion 10 is further illustrated based on FIG. 5, and the above described first filling portion 10 includes a first sub-filling portion 11 and a second sub-filling portion 12; wherein, an orthographic projection of the first sub-filling portion 11 on the plane on which the transparent substrate 57 is located are not overlapped with the orthographic projection of the light emitting unit on the plane on which the transparent substrate 57 is located; the second sub-filling portion 12 is at least partially located between the raised electrode 51 and the multiple quantum well layer 53, and the first sub-filling portion 11 surrounds a whole arrangement of the raised electrode 51, the multiple quantum well layer 53, and the second sub-filling portion 12.

For example, in order to ensure that the first filling portion 10 has a better protective effect, the first sub-filling portion 11 and the second sub-filling portion 12 are disposed in contact with each other, wherein a minimum distance n between an inner peripheral boundary and a peripheral boundary of the first sub-filling portion 11 is greater than or equal to 20 microns.

For example, a thickness of the first sub-filling portion 11 is equal to or greater than a distance between the first insulation layer 58 and the driving portion 6; a thickness of the second sub-filling portion 12 is equal to a maximum distance between the first insulation layer 58 and the driving portion 6. Thus, since the thickness of the first sub-filling portion 11 is greater than that of the second sub-filling portion 12, the first sub-filling portion 11 provides protection to the electrodes surrounded by the first sub-filling portion 11, and the second sub-filling portion 12 fills exactly the gap between the first insulation layer 58 and the driving portion 6 to prevent the solution from coming into contact with the electrodes through the gap during electroplating or electroless plating operation, thereby ensuring reliability of the devices. In some embodiments, the gap within an inside space surrounded by the first sub-filling part 11, the light emitting part 5, and the driving part 6 is all filled by the second sub-filling part 12, so that the solution erosion can be better isolated.

In some embodiments, the second sub-filling portion 12, the second filling portion 8, and the third filling portion 9 are formed by compressing an anisotropic conductive film; a relationship between a thickness H1 of the second sub-filling portion 12 before being compressed and a thickness H2 of the second sub-filling portion 12 satisfies: 0.5 H1<H2<0.95 H1. Herein, when H2 is less than 95% of H1, it is possible to avoid defects such as bubbles and delamination due to insufficient filling of the second sub-filling portion 12 in a thickness direction; and, when H2 is more than 50% of H1, it is possible to prevent the second sub-filling portion 12 from overflowing due to excessive thickness of the filling portion, wherein the overflowing causes fewer conductive particles in the second filling portion 8 and the third filling portion 9, resulting in conductive failure. For example, the thickness of the second sub-filling portion 12 can be determined by H2>k*d+1, where k is an upper limit of a compression ratio of the ACF in which the conductive particles have good conductivity, d is an average particle size of the conductive particles in a compression direction before compression, and 1 is a sum of the thickness of the first electrode 1 and the thickness of the third electrode 3. Therefore, k*d is a minimum degree of compression to make the conductive particles conductive in the compression direction. For example, H2−k*d+1. For example, H2>k*d+1. For example, when the average particle size in the compression direction is 2 microns, and the compression of the conductive particles by 20% to 80% is a good conductive range, then d is 2 microns and k is 80%. In this way, it can guide on how to design the thickness H2 of the second sub-filling portion 12.

In some embodiments, the second sub-filling portion 12, the second filling portion 8, and the third filling portion 9 are formed by compressing an anisotropic conductive film; the first sub-filling portion 11 includes at least a portion located between the transparent substrate 57 and the driving portion 6, and a relationship between a thickness T1 of the first sub-filling portion 11 located between the transparent substrate 57 and the driving portion 6 and a thickness T2 of the second sub-filling portion 12 satisfies: 0.5 T1<T2<0.95 T1. Herein, a portion of the first sub-filling portion 11 located between the transparent substrate 57 and the driving portion 6 may be slightly compressed (still in an insulation state), or may not be compressed. When the thickness T2 of the second sub-filling portion 12 is less than 95% of the thickness T1 of the first sub-filling portion 11, it is possible to avoid problems such as bubbles and delamination caused by insufficient filling of the second sub-filling portion 12 in the thickness direction; and, when the thickness T2 of the second sub-filling portion 12 is greater than 50% of the thickness T1 of the first sub-filling portion 11, it is possible to prevent the second sub-filling portion 12 from overflowing due to excessive thickness of the filling portion, wherein the overflowing causes fewer conductive particles in the second filling portion 8 and the third filling portion 9, resulting in conductive failure. For example, the thickness of the second sub-filling portion 12 can be determined by T2>k*d+1, where k is an upper limit of a compression ratio of the ACF in which the conductive particles have good conductivity, d is an average particle size of the conductive particles in a compression direction before compression, and 1 is a sum of the thickness of the first electrode 1 and the thickness of the third electrode 3. Therefore, k*d is a minimum degree of compression to make the conductive particles conductive in the compression direction. For example, T2−k*d+1. For example, T2>k*d+1. For example, when the average particle size in the compression direction is 2 microns, and the compression of the conductive particles by 20% to 80% is a good conductive range, then d is 2 microns and k is 80%. In this way, it can guide on how to design the thickness T2 of the second sub-filling portion 12.

For example, the first sub-filling portions 11 may all be located between the transparent substrate 57 and the driving portion 6; for another example, a portion of the first sub-filling portion 11 is located between the transparent substrate 57 and the driving portion 6, and the other portion is disposed protruding from the transparent substrate 57, that is, the orthographic projection of the first sub-filling portion 11 on the plane on which the transparent substrate 57 is located has a portion that is not overlapped with the transparent substrate.

Since the light emitting assembly includes a plurality of light emitting units and driving units corresponding to the plurality of light emitting units, the plurality of light emitting units include first color light emitting units, second color light emitting units, and third color light emitting units, wherein a first color emitted by a first color light emitting unit, a second color emitted by a second color light emitting unit, and a third color light emitting unit by a third color light emitting unit are different from each other, and the three colors may usually be red, green and blue. In order to be able to emit light of different colors to a screen, the light emitting unit needs to include a color film layer 56, a color conversion layer 55, and the light emitting portion 5 in the above-described embodiment, which are sequentially stacked in a direction away from the transparent substrate 57; a light emission color of the light emitting portion 5 is blue. Herein, the light emitting portion 5 includes a first light emitting portion located in the first color light emitting unit, a second light emitting portion located in the second color light emitting unit, and a third light emitting portion located in the third color light emitting unit. Since the light to be emitted is red, blue and green, but the light emitting unit 5 only emits blue light, the color conversion layer 55 needs to perform color conversion processing on the blue light, that is, the blue light becomes green light and red light, and then emits green light and red light. Since color conversion is not required for the color conversion layer 55 in the blue light portion, the color conversion layer 55 can be made of a transparent material, and then the light is displayed through the color film layer 56.

For the driving unit, the disposing of each level thereof can be disposed according to the actual demand, and as shown in FIG. 5, the driving unit includes a driving portion 6, a third electrode 3, and a fourth electrode 4, and the third electrode 3 and the fourth electrode 4 are located on the side of the driving unit 6 close to the light emitting unit; wherein, the driving unit 6 includes a base substrate 61 having connection vias, connection structures 64 located in the connection vias, the driving circuit 63 located on a side of the base substrate 61 close to the light emitting unit, and a planarization layer 62 located on a side of the driving circuit 63 close to the light emitting unit, and the planarization layer 62 is provided with vias through which the third electrode 3 and the fourth electrode 4 are electrically connected with the driving circuit 63. For example, each of the third electrode 3 and the fourth electrode 4 is disposed at least partially on the side of the driving unit facing the light emitting unit, and protrude from the planar layer 62. The pins 7 are located on a side of the base substrate 61 away from the driving circuit 63, and the pins 7 are in contact with the connection structures 64, and the pins 7 are connected with the driving circuit 63 through the connection structures 64. For example, areas of orthographic projections of the above-described pins 7 on the base substrate 61 are greater than areas of orthographic projections of the connection structures 64 on the base substrate 61, and the orthographic projections of the pins 7 on the substrate 61 cover the orthographic projections of the connection structures 64 on the base substrate 61.

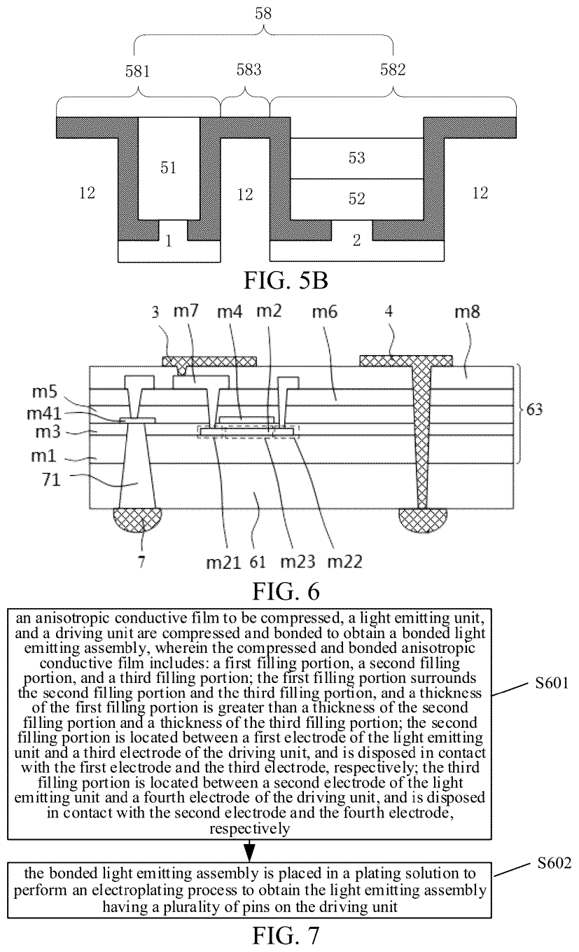

As shown in FIG. 6, the above-described driving circuit 63 includes: one or more thin film transistors, a thin film transistor including a gate m4, a source m7, and a drain m7; one pin 7 of the plurality of pins 7 is connected with the source m7 of the thin film transistor for supplying the driving circuit 63 with a data drive signal transmitted from the display backplane in the display panel. In the drawing, the pin 7 is connected with a gate connection portion m41 through a connection structure 71, and the gate connection portion m41 is connected with the source m7. Exemplarily, the driving circuit 63 may include a plurality of thin film transistors and at least one storage capacitor.

The driving circuit 63 may include a buffer layer m1, an active layer m2, a first gate insulation layer m3, a first gate layer m4, a second gate insulation layer m5, a second gate layer, an interlayer dielectric layer m6, a source-drain layer m7, and a planarization layer (62 in FIG. 5A is m8 in FIG. 6, in some embodiments, both the planarization layer 62 and m8 may exist, and 62 may be located on m8), which are stacked sequentially on a side of the base substrate 61; the third electrode 3 and the fourth electrode 4 are located on a side of the planarization layer 62/m8 away from the base substrate 61; alternatively, the second gate layer may also be located on a side of the active layer m2 away from the first gate layer m4.

The active layer m2 includes one or more active patterns corresponding to the one or more thin film transistors, each active pattern including a source region m21, a drain region m22, and a channel region m23; the source and the drain of the thin film transistor are located in the source-drain layer, the source and the source region m21 of the thin film transistor are connected, and the drain and the drain region m22 of the thin film transistor are connected; the first gate layer m4 includes one or more gate patterns corresponding to one or more thin film transistors, and the channel region m23 is an overlapping area of an orthographic projection of a gate pattern on the base substrate 61 and an orthographic projection of the active pattern on the base substrate 61.

For example, the buffer layer m1, the first gate insulation layer m3, the second gate insulation layer m5, and the interlayer dielectric layer m6 may be made of silicon oxide, silicon nitride, silicon oxynitride, or the like.

Exemplarily, the active layer m2 is made of a low-temperature poly-silicon material, and at this time, the driving unit 102 may also be referred to as an LTPS (Low Temperature Poly-Silicon) driving unit. Alternatively, the active layer m2 is made of a low-temperature poly-silicon material and a metal oxide semiconductor material such as IGZO (Indium Gallium Zinc Oxide), and at this time, the driving unit 102 may also be referred to as a LTPO (Low Temperature Polycrystalline Oxide) driving unit.

In some examples, the first gate layer m4 and the second gate layer may be made of a single metal layer, such as molybdenum, copper, aluminum, or the like. In other examples, the first gate layer m4 and the second gate layer may also include a plurality of metal layers stacked sequentially, for example, titanium, aluminum, titanium, etc. stacked sequentially.

Exemplarily, the planarization layer 62/m8 s made of an organic insulation material, such as a resin or the like.

Exemplarily, as illustrated, the first gate layer m4 further includes a gate connection portion m41 connected with the connection structure 71, and the gate connection portion m41 is used to connect with the connection structure 71 and a source of a data writing transistor. In order to connect the connection structure 71 and the gate connection portion m41, connection vias may also be disposed in the buffer layer m1 and the first gate insulation layer m3. Further, the connection structure 71 is located not only in the connection via of the base substrate 61, but also in the connection vias of the buffer layer m1 and the first gate insulation layer m3.

An embodiment of the present disclosure further provides a display panel, wherein the display panel includes at least a display backplane and a plurality of the above-described light emitting assemblies arranged in an array on one side of the display backplane; wherein, the display backplane is configured to supply drive signals to the driving units through the plurality of pins 7 in the light emitting assemblies, so that the driving units drive the light emitting units to emit light. The structure of the above-described light emitting assembly will not be repeated here.

In the embodiment of the present disclosure, the complex driving circuit 63 is independent of the display substrate (including a plurality of light emitting units), the driving substrate (including a plurality of driving units) only needs to dispose basic data lines, and the complex wiring of the driving circuit 63 is not required, the wiring structure on the driving substrate is very simple, the wiring difficulty of the driving substrate is exponentially reduced, and the difficulty of processing and manufacturing is also reduced, which is beneficial to industrial development.

The embodiment of the present disclosure also provides a manufacturing method of a light emitting assembly for manufacturing the above-described light emitting assembly, and the flow thereof is shown in FIG. 7, comprising steps S601 to S602:
S601, an anisotropic conductive film to be compressed, a light emitting unit, and a driving unit are compressed and bonded to obtain a bonded light emitting assembly, wherein the compressed and bonded anisotropic conductive film includes: a first filling portion 10, a second filling portion 8, and a third filling portion 9; the first filling portion 10 surrounds the second filling portion 8 and the third filling portion 9, and a thickness of the first filling portion 10 is greater than a thickness of the second filling portion 8 and a thickness of the third filling portion 9, respectively; the second filling portion 8 is located between a first electrode 1 of the light emitting unit and a third electrode 3 of the driving unit, and is disposed in contact with the first electrode 1 and the third electrode 3, respectively; the third filling portion 9 is located between a second electrode 2 of the light emitting unit and a fourth electrode 4 of the driving unit, and is disposed in contact with the second electrode 2 and the fourth electrode 4, respectively;
S602, the bonded light emitting assembly is placed in a target solution (such as a plating solution) to perform an electroplating process (or an electroless plating process) to obtain the light emitting assembly having a plurality of pins 7 on the driving unit.

In the embodiment of the present disclosure, in the process of bonding the light emitting unit and the driving unit, an anisotropic conductive film bonding method is used, and the anisotropic conductive film can play two functions: (1) compressing and bonding positions play circuit connection roles between the LEDs and the backplane; (2) the anisotropic conductive film at non-compressing and bonding positions is non-conductive, which plays a role in packaging and isolation, prevents the electroplating solution from immersing between the light emitting unit and the driving unit during the electroplating process of the preparation pins 7, and plays a role in anti-corrosion.

In addition, although the exemplary embodiments have been described herein, their scope includes any and all embodiments having equivalent elements, modifications, omissions, combinations (e.g., solutions formed among various embodiments), adaptations or changes based on the present disclosure. Elements in the claims will be broadly interpreted on the basis of the language used in the claims, and are not limited to the examples described in this specification or during the implementation of the present application, and the examples thereof will be interpreted to be non-exclusive. Therefore, this specification and the examples are intended to be considered to be exemplary only, and the true scope and essence will be indicated by the full range of the following claims and equivalents thereof.

The above description is intended to be illustrative and not limiting. For example, the above examples (or one or more solutions thereof) may be used in combination with each other. For example, other embodiments may be used by those of ordinary skills in the art upon reading the above description. In addition, in the above described implementations, various features may be grouped together to simplify the present disclosure. This should not be interpreted as an intention that an unclaimed disclosed feature is essential for any claim. On the contrary, the subject matter of the present disclosure may be less than all features of a particular disclosed embodiment. Therefore, the following claims are hereby incorporated into the embodiments as examples or embodiments, wherein each claim is independently used as a separate embodiment, and it is considered that these embodiments may be combined with each other in various combinations or arrangements. The scope of the present disclosure should be determined with reference to the full scope of the appended claims and equivalents to which these claims are entitled.

Multiple embodiments of the present disclosure are described above but not intended to limit the present disclosure. Those skilled in the art may make various transformations and modifications based on the concept of the present disclosure. These transformations and modifications shall fall in the scope of protection disclosed in the disclosure.

1. A light emitting assembly comprising:
a light emitting unit comprising a first electrode, a second electrode, and a light emitting portion electrically connected with the first electrode and the second electrode, respectively;
a driving unit comprising a third electrode, a fourth electrode, and a driving portion, wherein each of the third electrode and the fourth electrode is located on a side of the driving unit facing the light emitting unit, the third electrode and the fourth electrode are electrically connected with a driving circuit in the driving portion, respectively, the third electrode is electrically connected with the first electrode, and the fourth electrode is electrically connected with the second electrode; and
a plurality of pins, each located on a side of the driving unit facing away from the light emitting unit, and electrically connected with the driving circuit;
wherein a first filling portion, a second filling portion, and a third filling portion are included between the light emitting unit and the driving unit, the first filling portion surrounds the second filling portion and the third filling portion, and a thickness of the first filling portion is greater than a thickness of the second filling portion and a thickness of the third filling portion, respectively; the second filling portion is located between the first electrode and the third electrode, and is disposed in contact with the first electrode and the third electrode, respectively; the third filling portion is located between the second electrode and the fourth electrode, and is disposed in contact with the second electrode and the fourth electrode, respectively.

2. The light emitting assembly according to claim 1, wherein at least one pin of the plurality of pins comprises a first metal layer and a second metal layer that are stacked, and the first metal layer is located between the second metal layer and the driving unit;
wherein a material of the first metal layer comprises nickel, and a material of the second metal layer comprises gold.

3. The light emitting assembly according to claim 1, wherein
the first filling portion has insulation, the second filling portion has conductivity, and the third filling portion has conductivity;
the first filling portion is in direct contact with the second filling portion;
the first filling portion is in direct contact with the third filling portion;
a portion of the first filling portion is located between the second filling portion and the third filling portion.

4. The light emitting assembly according to claim 1, wherein
a density of the first filling portion is less than a density of the second filling portion;
the density of the first filling portion is less than a density of the third filling portion.

5. The light emitting assembly according to claim 1, wherein
the light emitting assembly comprises a transparent substrate located on a side of the light emitting unit away from the driving unit;
an orthographic projection of the first filling portion on a plane on which the transparent substrate is located within the transparent substrate.

6. The light emitting assembly according to claim 5, wherein
an outer contour of the orthographic projection of the first filling portion on the plane on which the transparent substrate is located coincides with an outer contour of the transparent substrate.

7. The light emitting assembly according to claim 1, wherein the light emitting assembly comprises a transparent substrate located on a side of the light emitting unit away from the driving unit;
the light emitting unit comprises a light emitting portion comprising:
a raised electrode, a first insulation layer, and a second doped layer, a multiple quantum well layer, and a first doped layer which are sequentially stacked in a direction away from the transparent substrate;
wherein the second electrode is located on a side of the first doped layer away from the multiple quantum well layer, and the first doped layer is electrically connected with the second electrode;
the raised electrode is located between the second doped layer and the first electrode, and is electrically connected with the second doped layer and the first electrode, respectively;
the first insulation layer is located on a side of the first doped layer away from the transparent substrate, and is disposed in contact with the first doped layer.

8. The light emitting assembly according to claim 7, wherein
the first filling portion comprises a first sub-filling portion and a second sub-filling portion;
an orthographic projection of the first sub-filling portion on a plane on which the transparent substrate is located is not overlapped with an orthographic projection of the light emitting unit on the plane on which the transparent substrate is located;
wherein the second sub-filling portion is at least partially located between the raised electrode and the multiple quantum well layer, and the first sub-filling portion surrounds a whole arrangement of the raised electrode, the multiple quantum well layer, and the second sub-filling portion.

9. The light emitting assembly according to claim 8, wherein
a thickness of the first sub-filling portion is greater than or equal to a distance between the first insulation layer and the driving portion;
a thickness of the second sub-filling portion is equal to a maximum distance between the first insulation layer and the driving portion.

10. The light emitting assembly according to claim 9, wherein
the first sub-filling portion comprises at least a portion located between the transparent substrate and the driving portion;
a relationship between a thickness T1 of the first sub-filling portion located between the transparent substrate and the driving portion and a thickness T2 of the second sub-filling portion satisfies:
0.5 T1<T2<0.95 T1.

11. The light emitting assembly according to claim 5, wherein
the light emitting assembly comprises a plurality of light emitting units and driving units corresponding to the plurality of light emitting units; the plurality of light emitting units comprise first color light emitting units, second color light emitting units, and third color light emitting units, wherein a first color emitted by a first color light emitting unit, a second color emitted by a second color light emitting unit, and a third color light emitting unit by a third color light emitting unit are different from each other;
a light emitting unit comprises a color film layer, a color conversion layer, and a light emitting portion which are sequentially stacked in a direction away from the transparent substrate; a light emission color of the light emitting portion is blue;
wherein the light emitting portion comprises a first light emitting portion located in the first color light emitting unit, a second light emitting portion located in the second color light emitting unit, and a third light emitting portion located in the third color light emitting unit.

12. The light emitting assembly according to claim 1, wherein the driving unit comprises a base substrate having connection vias and connection structures located in the connection vias, and the driving circuit being located on a side of the base substrate close to the light emitting unit;
the pins are located on a side of the base substrate away from the driving circuit, and the pins are in contact with the connection structures, and the pins are connected with the driving circuit through the connection structures.

13. The light emitting assembly according to claim 12, wherein the driving circuit comprises one or more thin film transistors, and a thin film transistor comprises a gate, a source, and a drain;
one of the plurality of pins is connected with the source of the thin film transistor for supplying the driving circuit with a data drive signal transmitted from a display backplane in a display panel.

14. The light emitting assembly according to claim 13, wherein the driving circuit comprises a buffer layer, an active layer, a first gate insulation layer, a first gate layer, a second gate insulation layer, a second gate layer, an interlayer dielectric layer, a source-drain layer, and a planarization layer which are sequentially stacked on a side of the base substrate;
the third electrode and the fourth electrode are located on a side of the planarization layer away from the base substrate;
the active layer comprises one or more active patterns corresponding to the one or more thin film transistors, an active pattern comprising a source region, a drain region, and a channel region;
the source and the drain of the thin film transistor are located in the source-drain layer, the source of the thin film transistor are connected with the source region, and the drain of the thin film transistor are connected with the drain region;
the first gate layer comprises one or more gate patterns corresponding to the one or more thin film transistors, and the channel region is an overlapping area of an orthographic projection of a gate pattern on the base substrate and an orthographic projection of the active pattern on the base substrate.

15. The light emitting assembly according to claim 12, wherein areas of orthographic projections of the pins on the base substrate are greater than areas of orthographic projections of the connection structures on the base substrate, and the orthographic projections of the pins on the base substrate cover the orthographic projections of the connection structures on the base substrate.

16. A display panel, wherein the display panel comprises a display backplane and a plurality of the light emitting assemblies according to claim 1 arranged in an array on a side of the display backplane;
wherein the display backplane is configured to supply drive signals to the driving units through a plurality of pins in the light emitting assemblies, so that the driving units drive the light emitting units to emit light.

17. A manufacturing method of a light emitting assembly for manufacturing the light emitting assembly according to claim 1, comprising:
an anisotropic conductive film to be compressed, a light emitting unit, and a driving unit are compressed and bonded to obtain a bonded light emitting assembly, wherein the compressed and bonded anisotropic conductive film comprises: a first filling portion, a second filling portion, and a third filling portion; the first filling portion surrounds the second filling portion and the third filling portion, and a thickness of the first filling portion is greater than a thickness of the second filling portion and a thickness of the third filling portion, respectively; the second filling portion is located between a first electrode of the light emitting unit and a third electrode of the driving unit, and is disposed in contact with the first electrode and the third electrode, respectively; the third filling portion is located between a second electrode of the light emitting unit and a fourth electrode of the driving unit, and is disposed in contact with the second electrode and the fourth electrode, respectively;
the bonded light emitting assembly is placed in a target solution to perform an electroplating process or an electroless plating process, to obtain the light emitting assembly having a plurality of pins on the driving unit.

18. The light emitting assembly according to claim 7, wherein
the light emitting assembly comprises a plurality of light emitting units and driving units corresponding to the plurality of light emitting units; the plurality of light emitting units comprise first color light emitting units, second color light emitting units, and third color light emitting units, wherein a first color emitted by a first color light emitting unit, a second color emitted by a second color light emitting unit, and a third color light emitting unit by a third color light emitting unit are different from each other;
a light emitting unit comprises a color film layer, a color conversion layer, and a light emitting portion which are sequentially stacked in a direction away from the transparent substrate; a light emission color of the light emitting portion is blue;
wherein the light emitting portion comprises a first light emitting portion located in the first color light emitting unit, a second light emitting portion located in the second color light emitting unit, and a third light emitting portion located in the third color light emitting unit.

19. The light emitting assembly according to claim 2, wherein the driving unit comprises a base substrate having connection vias and connection structures located in the connection vias, and the driving circuit being located on a side of the base substrate close to the light emitting unit;
the pins are located on a side of the base substrate away from the driving circuit, and the pins are in contact with the connection structures, and the pins are connected with the driving circuit through the connection structures.

20. The light emitting assembly according to claim 3, wherein the driving unit comprises a base substrate having connection vias and connection structures located in the connection vias, and the driving circuit being located on a side of the base substrate close to the light emitting unit;
the pins are located on a side of the base substrate away from the driving circuit, and the pins are in contact with the connection structures, and the pins are connected with the driving circuit through the connection structures.
